(19) United States
(12) Patent Application Publication
(10) Pub. No.: US 2026/0143681 A1
(43) Pub. Date: May 21, 2026

(54) SEMICONDUCTOR DEVICE AND METHOD OF FABRICATING THE SAME USING A CONTACT SACRIFICIAL LAYER

(71) Applicant: Samsung Electronics Co., Ltd., Suwon-si (KR)

(72) Inventors: Seungmin Lee, Suwon-si (KR); Gunjoo Woo, Suwon-si (KR); Donghyeon Lee, Suwon-si (KR); Chankyu Lee, Suwon-si (KR)

(21) Appl. No.: 19/390,770

(22) Filed: Nov. 17, 2025

(30) Foreign Application Priority Data
Nov. 20, 2024 (KR) 10-2024-0166610

(51) Int. Cl. H10B 12/00; H01L 23/00; H01L 25/065; H01L 25/18; H10B 80/00

(52) U.S. Cl. CPC H10B 12/33; H10B 12/05; H10B 80/00; H10W 90/00; H10W 90/792

(57) ABSTRACT

A semiconductor device includes a capacitor, a contact structure arranged on the capacitor and including a first contact metal in contact with the capacitor and a second contact metal, which is not in contact with the capacitor and is in contact with the first contact metal, a vertical channel layer extending on the first contact metal in a vertical direction and including an oxide semiconductor material including indium (In), a first gate dielectric layer in contact with a sidewall of the vertical channel layer, a second gate dielectric layer in contact with a top surface of the second contact metal and a sidewall of the first gate dielectric layer, a word line on an inner wall of the second gate dielectric layer, and a bit line in contact with a top surface of the vertical channel layer and extending in a horizontal direction.

### CROSS-REFERENCE TO RELATED APPLICATION

This application is based on and claims priority under 35 U.S.C. § 119 to Korean Patent Application No. 10-2024-0166610, filed on Nov. 20, 2024, in the Korean Intellectual Property Office, the disclosure of which is incorporated by reference herein in its entirety.

### BACKGROUND

The present disclosure relates to a semiconductor device and a method of fabricating the same, and more particularly, to a semiconductor device including a vertical channel transistor and a method of fabricating the semiconductor device.

To meet high performance and economic feasibility, it is necessary to increase the integration density of integrated circuit devices. In particular, the integration density of memory devices is an important factor in determining the economic feasibility of products. The integration density of two-dimensional (2D) memory devices is mainly determined by the area of a memory cell unit and is thus greatly influenced by the level of a micropatterning technique. However, because expensive equipment is needed to form micropatterns and the area of a chip die is limited, the integration density of 2D memory devices is still limited, although it is increasing.

### SUMMARY

An aspect provides a semiconductor device including a vertical channel transistor and capable of increasing the reliability of products by improving electrical characteristics.

An aspect also provides a method of fabricating a semiconductor device including a vertical channel transistor and capable of increasing the reliability of products by improving electrical characteristics.

The inventive concept is not limited to what is mentioned above and will be clearly understood by those skilled in the art from the descriptions below.

According to an aspect, there is provided a semiconductor device including a capacitor, a contact structure arranged on the capacitor and including a first contact metal and a second contact metal, the first contact metal being in contact with the capacitor, and the second contact metal not being in contact with the capacitor and being in contact with the first contact metal, a vertical channel layer extending on the first contact metal in a vertical direction and including an oxide semiconductor material including indium, a first gate dielectric layer in contact with a sidewall of the vertical channel layer, a second gate dielectric layer in contact with a top surface of the second contact metal and a sidewall of the first gate dielectric layer, a word line on an inner wall of the second gate dielectric layer, and a bit line in contact with a top surface of the vertical channel layer and extending in a horizontal direction.

According to another aspect, there is provided a semiconductor device including a peripheral circuit region including a peripheral circuit transistor and a cell array region on the peripheral circuit region, wherein the cell array region includes a cell wiring structure, a bit line extending in a horizontal direction on the cell wiring structure, a vertical channel layer extending on the bit line in a vertical direction and including an oxide semiconductor material including indium, a first gate dielectric layer in contact with a sidewall of the vertical channel layer, a second gate dielectric layer in contact with a sidewall of the first gate dielectric layer, a word line on an inner wall of the second gate dielectric layer, a contact structure arranged on the vertical channel layer and the second gate dielectric layer and including a first contact metal and a second contact metal, the first contact metal being in contact with the vertical channel layer, and the second contact metal being in contact with the second gate dielectric layer and the first contact metal, and a capacitor on the contact structure.

According to a further aspect, there is provided a method of fabricating a semiconductor device. The method includes forming a capacitor on a substrate, forming a contact sacrificial layer on the capacitor, forming a mold layer vertically above the contact sacrificial layer, the mold layer protruding in a vertical direction, forming an oxide semiconductor material layer conformally covering the contact sacrificial layer and the mold layer, forming a gate dielectric material layer covering the oxide semiconductor material layer, forming a vertical channel layer and a first gate dielectric layer on a sidewall of the mold layer by etching the oxide semiconductor material layer and the gate dielectric material layer, forming a contact forming space on the capacitor by removing the contact sacrificial layer, the contact forming space being defined by a first side surface of an insulating layer, a second side surface of the insulating layer and a top surface of the capacitor; forming a first contact metal layer conformally covering the first gate dielectric layer and the first side surface of the insulating layer, the second side surface of the insulating layer and the top surface of the capacitor defining the contact forming space, forming a first contact metal by etching the first contact metal layer, forming a second contact metal on the first contact metal, forming a second gate dielectric layer conformally covering the first gate dielectric layer and the second contact metal, forming a word line on an inner wall of the second gate dielectric layer, and forming a bit line contacting the vertical channel layer and extending in a horizontal direction.

According to a further aspect, there is provided semiconductor devices produced by the present methods.

According to a further aspect, there are provided semiconductor packages including the present semiconductor devices.

### BRIEF DESCRIPTION OF THE DRAWINGS

Embodiments will be more clearly understood from the following detailed description taken in conjunction with the accompanying drawings in which:

FIG. 1 is a perspective view of a semiconductor device according to an embodiment;

FIG. 2 is a cross-sectional view taken along line A-A′ in FIG. 1;

FIG. 3 is an enlarged view of a region CX in FIG. 2;

FIG. 4 is a perspective view of a semiconductor device according to an embodiment;

FIG. 5 is a cross-sectional view taken along line B-B′ in FIG. 4;

FIG. 6 is a flowchart of a method of fabricating a semiconductor device, according to an embodiment;

FIGS. 7 to 20 are cross-sectional views of sequential stages in a method of fabricating a semiconductor device, according to an embodiment; and

FIG. 21 is a block diagram of a system including a semiconductor device, according to an embodiment.

### DETAILED DESCRIPTION OF THE EMBODIMENTS

Hereinafter, embodiments are described in detail with reference to the accompanying drawings.

Herein, the terms “top/bottom”, “upper/lower”, “above/below”, etc. are used based on the directions shown in the accompanying drawings. Accordingly, even the same surface may be referred to as a top surface or a lower surface depending on the direction shown in the drawings. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the term “below”, for example, can encompass both an orientation of above and below. The device may be otherwise oriented (rotated 90 degrees or at other orientations) and the spatially relative descriptors used herein interpreted accordingly.

The semiconductor device may be a semiconductor chip (i.e., a semiconductor device singulated from (e.g., cut from) a wafer).

It will be understood that when an element is referred to as being “connected” to or “on” another element, it can be directly connected to or on the other element or intervening elements may be present. In contrast, when an element is referred to as “contacting” or “in contact with” another element (or using any form of the word “contact”), there are no intervening elements present at the point of contact.

As used herein the terms “cover” or “covering” are intended to mean that an element is over or aside another element. The elements may be touching or not. For example, there may be layers between layers that are “covering” one another. An element “covering” another element need not cover an entire top surface of an element below to be considered “covering”. The terms are intended to encompass one element “covering” all, or any part of, an element below it.

Terms such as “same,” “equal,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” or “substantially equal,” may be exactly the same or equal, or may be the same, or equal within acceptable variations that may occur, for example, due to manufacturing processes.

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

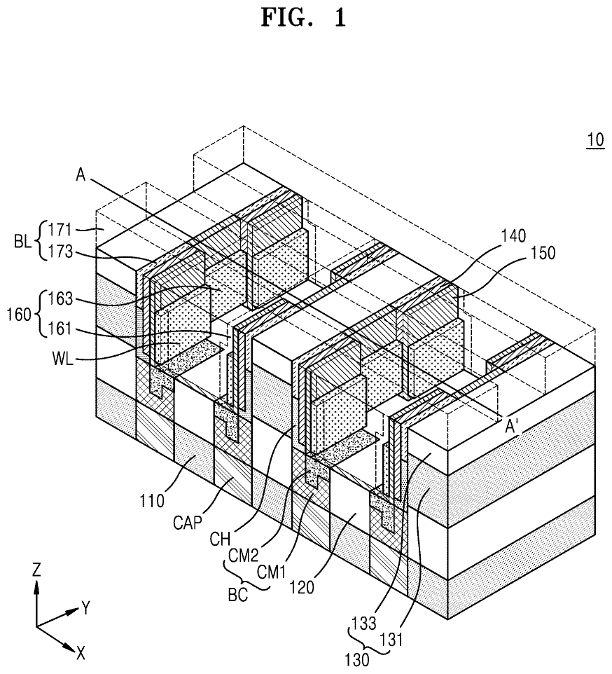

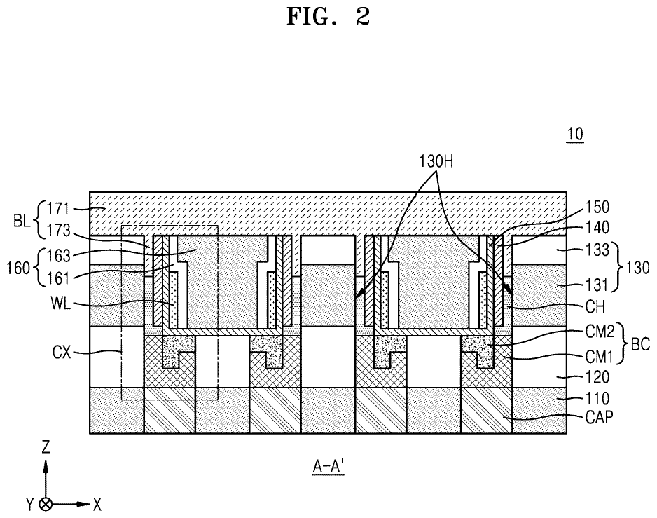

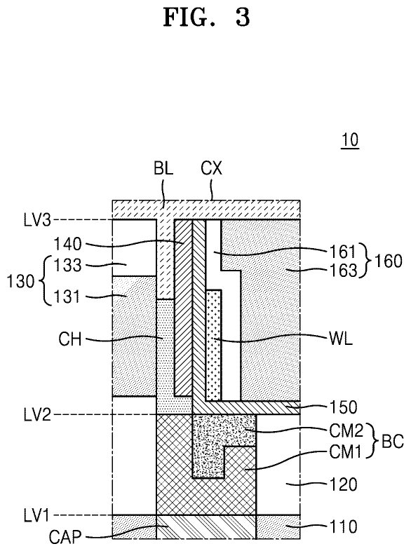

FIG. 1 is a perspective view of a semiconductor device 10 according to an embodiment. FIG. 2 is a cross-sectional view taken along line A-A′ in FIG. 1. FIG. 3 is an enlarged view of a region CX in FIG. 2.

Referring to FIGS. 1 to 3, the semiconductor device 10 may include memory cells including a vertical channel transistor (VCT).

In the semiconductor device 10, a plurality of capacitors CAP may be apart from each other in a first horizontal direction (an X direction). In some embodiments, each of the capacitors CAP may include a metal-insulator-metal type capacitor. For example, each of the capacitors CAP may include a first electrode, a second electrode, and a capacitor dielectric layer between the first electrode and the second electrode.

A plurality of contact structures BC may be disposed on the capacitors CAP. One contact structure BC may include a first contact metal CM1 and a second contact metal CM2. The first contact metal CM1 may have, for example, a stepped shape, and the second contact metal CM2 may have an inverted L-shape (or a shape symmetrical with the inverted L-shape). A stepped shape may include shapes that have both steps down and up, and the steps may be the same or different lengths. A convex-concave shape of the first contact metal CM1 may be fitted into a convex-concave shape of the second contact metal CM2.

In some embodiments, the first contact metal CM1 may be in contact with a capacitor CAP at a first vertical level LV, and the second contact metal CM2 may be in contact with the first contact metal CM1 and may not be in contact with the capacitor CAP. In some embodiments, the first contact metal CM1 may include molybdenum (Mo), ruthenium (Ru), or titanium nitride (TiN), and the second contact metal CM2 may include titanium (Ti).

In the semiconductor device 10, the contact structure BC may be referred to as a buried contact. The contact structure BC is described in detail below.

A first insulating layer 110 may be between two adjacent capacitors CAP, and a second insulating layer 120 may be between two adjacent contact structures BC. The first insulating layer 110 may include silicon oxide, silicon nitride, silicon carbide, or a combination thereof. The second insulating layer 120 may include silicon oxide, silicon nitride, silicon carbide, or a combination thereof. The first insulating layer 110 and the second insulating layer 120 may include different materials from each other. In some embodiments, the first insulating layer 110 may include silicon oxide, and the second insulating layer 120 may include silicon nitride.

A mold layer 130 may be disposed on the second insulating layer 120. The mold layer 130 may include a plurality of mold openings 130H. In some embodiments, the mold layer 130 may include a plurality of mold insulating layers stacked in a vertical direction (a Z direction). For example, the mold layer 130 may include a first mold insulating layer 131 and a second mold insulating layer 133. In some embodiments, the first mold insulating layer 131 may include silicon oxide, and the second mold insulating layer 133 may include silicon nitride.

A plurality of vertical channel layers CH may be respectively disposed on the plurality of contact structures BC. A plurality of vertical channel layers CH may respectively be in contact with opposite sidewalls of the mold layer 130 in each of the mold openings 130H. In detail, one vertical channel layer CH may have an L-shape (or a shape symmetrical with the L-shape).

In some embodiments, the bottom surface of the vertical channel layer CH may be in contact with the top surface of the first contact metal CM1 at a second vertical level LV2 and may not be in contact with the top surface of the second contact metal CM2. In some embodiments, the vertical channel layer CH may include an oxide semiconductor material. The oxide semiconductor material may include indium (In). For example, the oxide semiconductor material may include at least one oxide semiconductor material selected from the group consisting of InGaZnOₓ (IGZO), Sn-doped IGZO, W-doped IGZO, and InZnOₓ (IZO) but is not limited thereto.

A plurality of first gate dielectric layers 140 may be respectively disposed on the plurality of vertical channel layers CH, each first gate dielectric layer 140 being on a corresponding vertical channel layer CH. In detail, a first gate dielectric layer 140 may be disposed lengthwise in the vertical direction (the Z direction) on the inner wall of the L-shape (or the shape symmetrical shape with the L-shape) of one vertical channel layer CH. The first gate dielectric layer 140 may include a high-k dielectric material having a higher dielectric constant than silicon oxide. In some embodiments, the first gate dielectric layer 140 may have a dielectric constant of about 10 to about 25, or about 13 to about 22, or about 15 to about 20. For example, the first gate dielectric layer 140 may include, but not be limited to, HfO₂, Al₂O₃, HfAlO₃, Ta₂O₃, TiO₂, or a combination thereof.

A second gate dielectric layer 150 may be conformally disposed on the top surface of a pair of second contact metals CM2 and the sidewall of a pair of first gate dielectric layers 140. In detail, the second gate dielectric layer 150 may have a U-shape. The second gate dielectric layer 150 may include a high-k dielectric material and may include a different material than the first gate dielectric layer 140.

In some embodiments, the length of the second gate dielectric layer 150 in the vertical direction (the Z direction) may be greater than the length of the first gate dielectric layer 140 in the vertical direction (the Z direction). For example, the level of the top surface of the second gate dielectric layer 150 may be substantially the same as the level of the top surface of the first gate dielectric layer 140 in the vertical direction, but the level of the bottom surface of the second gate dielectric layer 150 may be lower than the level of the bottom surface of the first gate dielectric layer 140 in the vertical direction.

A pair of word lines WL may be arranged inside the second gate dielectric layer 150 to be apart from each other and face each other in the first horizontal direction (the X direction). Each of the word lines WL may be disposed on an inner wall of the second gate dielectric layer 150 and may extend in a second horizontal direction (a Y direction) crossing the first horizontal direction (the X direction). In some embodiments, a word line WL may include Ti, TiN, Ta, TaN, W, WN, TiSiN, WSiN, polysilicon, or a combination thereof.

An internal insulating layer 160 may be arranged in one mold opening 130H to cover a pair of word lines WL and one second gate dielectric layer 150. In detail, a pair of first internal insulating layers 161 may be arranged to conformally cover the pair of word lines WL, and a second internal insulating layer 163 may be arranged between the first internal insulating layers 161. In some embodiments, the first internal insulating layers 161 may include silicon nitride, and the second internal insulating layer 163 may include silicon oxide.

A bit line BL may extend in the first horizontal direction (the X direction) at a third vertical level LV3 on the mold layer 130 and the internal insulating layer 160. A bit line insulating layer (not shown) may extend in the first horizontal direction (the X direction) on a sidewall of the bit line BL. For example, the bit line insulating layer may fill the space between two adjacent bit lines BL and have the same height as the bit lines BL. In some embodiments, a bit line BL may include Ti, TiN, Ta, TaN, W, WN, TiSiN, WSiN, polysilicon, or a combination thereof.

In some embodiments, the bit line BL may include a horizontal extension 171 extending in the first horizontal direction (the X direction) and a plurality of vertical protrusions 173 protruding from the horizontal extension 171 in the vertical direction (the Z direction). The bottom surface of one vertical protrusion 173 of the bit line BL may be in contact with the top surface of the vertical channel layer CH. In some embodiments, a sidewall of one vertical protrusion 173 of the bit line BL may be in contact with a sidewall of the mold layer 130 and an opposite sidewall of the one vertical protrusion 173 may be in contact with a sidewall of the first gate dielectric layer 140.

To meet high performance and economic feasibility, it is necessary to increase the integration density of integrated circuit devices. In particular, the integration density of memory devices is an important factor in determining the economic feasibility of products. The integration density of two-dimensional (2D) memory devices is mainly determined by the area of a memory cell unit and is thus greatly influenced by the level of a micropatterning technique. However, because expensive equipment is needed to form micropatterns and the area of a chip die is limited, the integration density of 2D memory devices is still limited, although it is increasing. Accordingly, the demand for a semiconductor device including a vertical channel transistor is increasing.

In general, because the size of a cell transistor of a semiconductor device including a vertical channel transistor may be reduced with the increase of the integration density of the semiconductor device, the contact area between a buried contact and a vertical channel layer is decreasing. When the vertical channel includes an oxide semiconductor material, such as IGZO, and the contact area is reduced, the exposed top surface of the buried contact may also be oxidized in a process of supplying oxygen (O₂) to increase the performance of the vertical channel layer after the vertical channel layer is formed. Accordingly, the electrical characteristics of the semiconductor device may degrade, and the reliability of products may decrease.

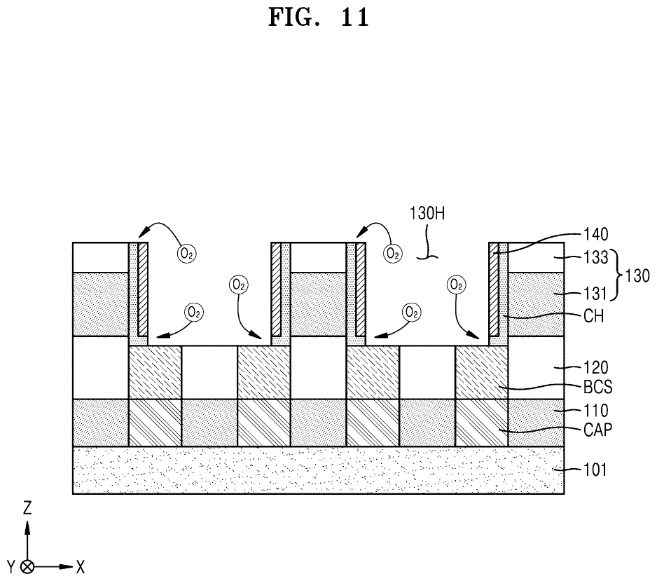

According to embodiments, the semiconductor device 10 may prevent oxidation of the contact structure BC, which functions as a buried contact in a vertical channel transistor structure, by replacing a contact sacrificial layer (BCS in FIG. 11) with the contact structure BC. In addition, hydrogen (H₂) generated during a heat treatment may be prevented from diffusing by forming the second contact metal CM2, i.e., a portion of the contact structure BC, using titanium (Ti) having excellent H₂ capture effect.

Consequently, the semiconductor device 10 may efficiently reduce contact resistance by preventing an oxide layer from being formed on a contact surface between the contact structure BC and the vertical channel layer CH and may allow the contact structure BC to prevent the diffusion of hydrogen (H₂) generated during a heat treatment, thereby improving the electrical characteristics and increasing the reliability of products.

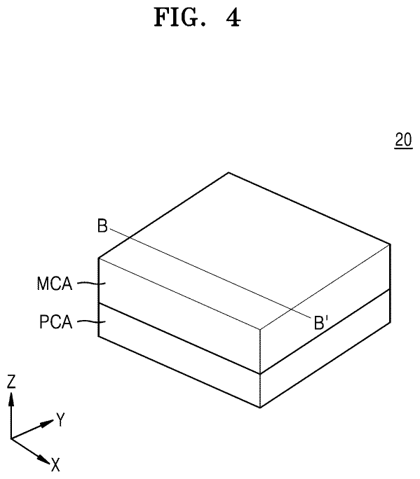

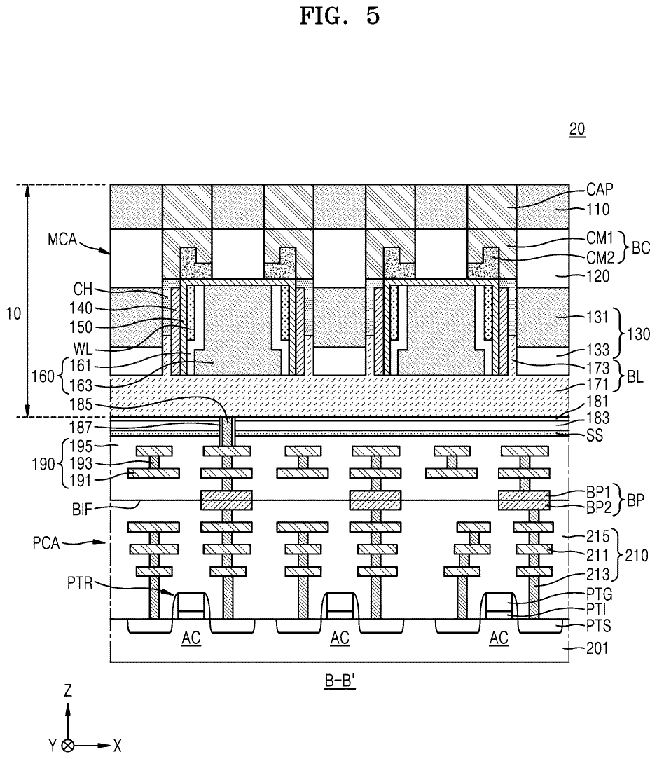

FIG. 4 is a perspective view of a semiconductor device 20 according to an embodiment. FIG. 5 is a cross-sectional view taken along line B-B′ in FIG. 4.

The elements of a cell array region MCA of the semiconductor device 20 and the materials of the elements described below are mostly and substantially the same as, the same as, or similar to those described above with reference to FIGS. 1 to 3. For convenience of description, therefore, the semiconductor device 20 is described focusing on the differences from the semiconductor device 10.

Referring to FIGS. 4 and 5, the semiconductor device 20 may include a peripheral circuit region PCA and a cell array region MCA at a higher vertical level than the peripheral circuit region PCA.

In some embodiments, the cell array region MCA may correspond to a memory cell region of a dynamic random-access memory (DRAM) device, and the peripheral circuit region PCA may correspond to a core region or peripheral circuit region of the DRAM device. For example, the peripheral circuit region PCA may include a peripheral circuit transistor PTR transmitting a signal and/or power to a memory cell array included in the cell array region MCA. In some embodiments, the peripheral circuit transistor PTR may form various circuits, such as a command decoder, a control logic, an address buffer, a row decoder, a column decoder, a sense amplifier, and a data input/output circuit.

A substrate 201 may include silicon, such as monocrystalline silicon, polycrystalline silicon, or amorphous silicon. The substrate 201 may include at least one selected from the group consisting of Ge, SiGe, SiC, GaAs, InAs, and InP. In some embodiments, the substrate 201 may include a conductive region, e.g., an impurity-doped well or an impurity-doped structure.

In the peripheral circuit region PCA, the substrate 201 may include an active region AC, and the peripheral circuit transistor PTR may be arranged on the active region AC of the substrate 201. The peripheral circuit transistor PTR may include a gate electrode PTG, a gate insulating layer PTI, or a source/drain region PTS.

A peripheral circuit wiring structure 210 may be arranged on the substrate 201 to cover the peripheral circuit transistor PTR. The peripheral circuit wiring structure 210 may include a peripheral circuit wire 211, a peripheral circuit contact 213, and a peripheral circuit insulating layer 215. The peripheral circuit wire 211 and the peripheral circuit contact 213 may be electrically connected to the peripheral circuit transistor PTR and/or the substrate 201. The peripheral circuit insulating layer 215 may be arranged on the substrate 201 to cover the peripheral circuit transistor PTR, the peripheral circuit wire 211, and the peripheral circuit contact 213. The peripheral circuit insulating layer 215 may include silicon oxide, silicon nitride, a low-k dielectric material, or a combination thereof and may have a stack structure of a plurality of insulating layers.

The peripheral circuit region PCA may be attached to the cell array region MCA in a bonding manner. In some embodiments, the boundary surface between the peripheral circuit region PCA and the cell array region MCA may be referred to as a bonding interface BIF. For example, a portion of the semiconductor device 20, which is below the vertical level of the bonding interface BIF, may be referred to as the peripheral circuit region PCA, and a portion of the semiconductor device 20, which is above the vertical level of the bonding interface BIF, may be referred to as the cell array region MCA.

In some embodiments, the peripheral circuit wiring structure 210 may be in contact with a cell wiring structure 190 at the bonding interface BIF. The cell wiring structure 190 may include a cell wiring layer 191, a cell contact 193, and a cell insulating layer 195.

A bonding pad BP may be arranged on the boundary surface (i.e., the bonding interface BIF) between the cell wiring structure 190 and the peripheral circuit wiring structure 210. The bonding pad BP may include a first bonding pad BP1 and a second bonding pad BP2. The bottom surface of the first bonding pad BP1 may be at the same level as the bottom surface of the cell insulating layer 195, the top surface of the second bonding pad BP2 may be at the same level as the top surface of the peripheral circuit insulating layer 215, and the bottom surface of the first bonding pad BP1 may be in contact with the top surface of the second bonding pad BP2.

In some embodiments, the cell wiring structure 190 and the peripheral circuit wiring structure 210 may be bonded to each other by a metal-oxide hybrid bonding method. In this case, the boundary surface between the peripheral circuit insulating layer 215 and the cell insulating layer 195 may be coplanar with the boundary surface between the first bonding pad BP1 and the second bonding pad BP2. For example, the boundary surface between the peripheral circuit insulating layer 215 and the cell insulating layer 195 and the boundary surface between the first bonding pad BP1 and the second bonding pad BP2 may be arranged along the bonding interface BIF.

In some embodiments, the cell wiring structure 190 and the peripheral circuit wiring structure 210 may be bonded to each other by an oxide bonding method. In this case, the bonding pad BP may be omitted.

In the vertical direction (the Z direction), a bit line BL may be on the cell wiring structure 190, a vertical channel layer CH may be on the bit line BL, a contact structure BC may be on the vertical channel layer CH, and a capacitor CAP may be on the contact structure BC. For example, the semiconductor device 10 described above may be arranged upside down on the cell wiring structure 190.

Consequently, the semiconductor device 20 may have a bonding structure that efficiently reduces contact resistance by preventing an oxide layer from being formed on a contact surface between the contact structure BC and the vertical channel layer CH and allows the contact structure BC to prevent the diffusion of hydrogen (H₂) generated during a heat treatment, thereby improving the electrical characteristics and increasing the reliability of products.

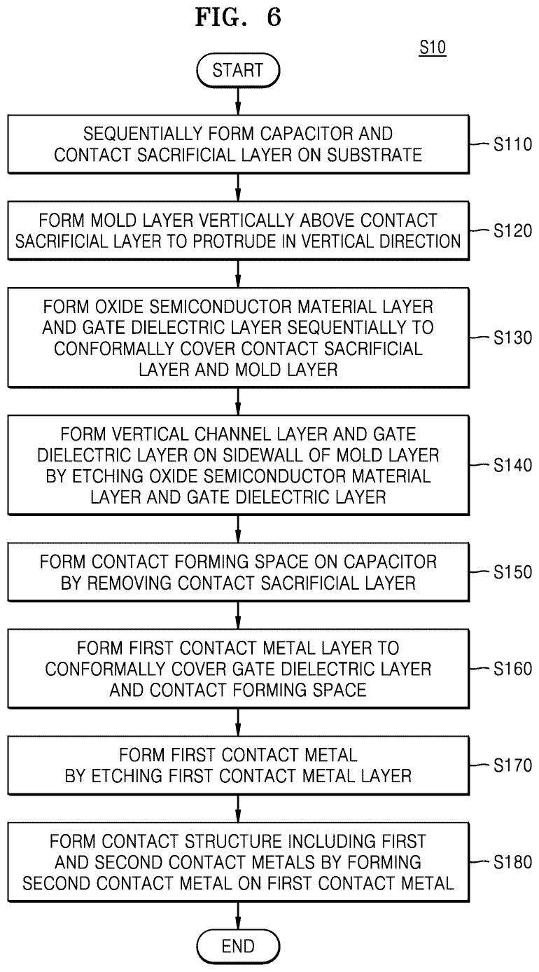

FIG. 6 is a flowchart of a method of fabricating a semiconductor device, according to an embodiment.

Referring to FIG. 6, a method S10 of fabricating a semiconductor device may sequentially include first to eighth operations S110 to S180.

When it is possible to modify an embodiment, the order of operations may be different from the order in which the operations are described. For instance, two operations described as being performed sequentially may be substantially performed simultaneously or in a reverse order.

The method S10 may include sequentially forming a capacitor and a contact sacrificial layer on a substrate in the first operation S110, forming a mold layer vertically above the contact sacrificial layer, the mold layer protruding in the vertical direction in the second operation S120, sequentially forming an oxide semiconductor material layer and a gate dielectric material layer to conformally cover the contact sacrificial layer and the mold layer in the third operation S130, forming a vertical channel layer and agate dielectric layer on a sidewall of the mold layer by etching the oxide semiconductor material layer and the gate dielectric material layer in the fourth operation S140, forming a contact forming space on the capacitor by removing the contact sacrificial layer in the fifth operation S150, forming a first contact metal layer to conformally cover the gate dielectric layer and the contact forming space (for example side walls of the second insulating layer and a top surface of the capacitor) in the sixth operation S160, forming a first contact metal by etching the first contact metal layer in the seventh operation S170, and forming a contact structure including first and second contact metals by forming the second contact metal on the first contact metal in the eighth operation S180.

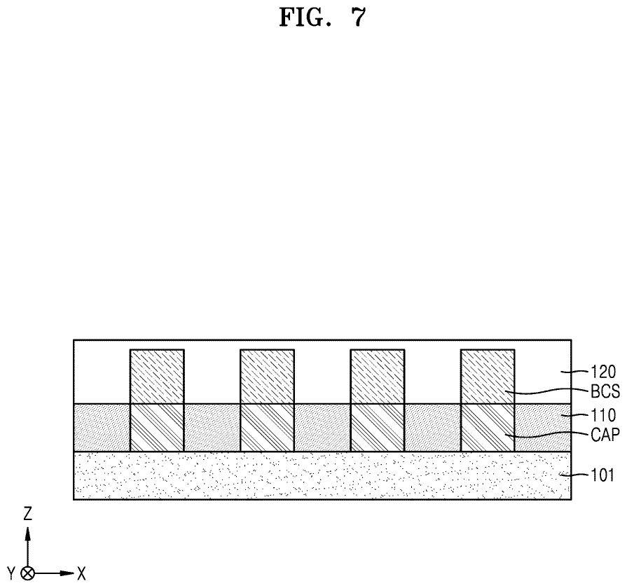

The technical characteristics of each of the first to eighth operations S110 to S180 are described in detail below with reference to FIGS. 7 to 20.

FIGS. 7 to 20 are cross-sectional views of sequential stages in a method of fabricating an integrated circuit device, according to an embodiment.

Referring to FIG. 7, a plurality of capacitors CAP may be formed on a carrier substrate 101, and a plurality of contact sacrificial layers BCS may be respectively formed on the capacitors CAP.

In some embodiments, the first insulating layer 110 may be formed first on the carrier substrate 101, a plurality of capacitor openings may be formed through the first insulating layer 110, and the capacitors CAP may be respectively formed in the capacitor openings.

In some embodiments, the contact sacrificial layers BCS may be respectively formed on the capacitors CAP, and the second insulating layer 120 may be formed to cover the sidewalls and top surfaces of the contact sacrificial layers BCS.

In some embodiments, the first insulating layer 110 may include silicon oxide, and the second insulating layer 120 may include silicon nitride.

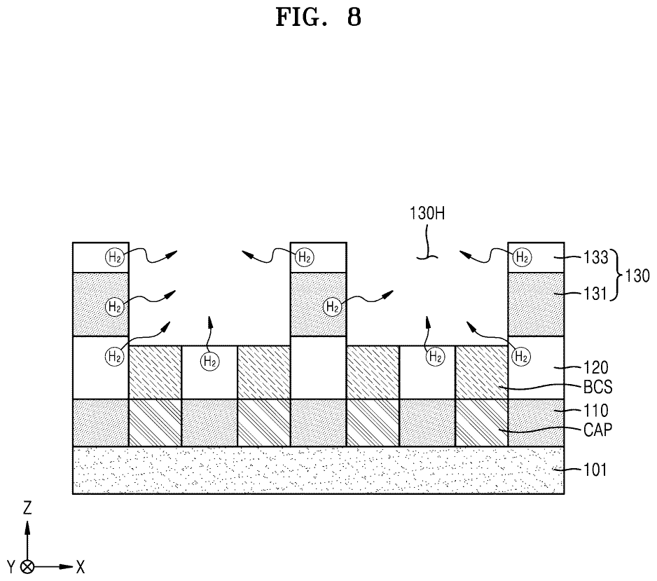

Referring to FIG. 8, the mold layer 130 having the mold openings 130H may be formed on a plurality of contact sacrificial layers BCS and the second insulating layer 120.

In some embodiments, the mold layer 130 may include the first mold insulating layer 131 and the second mold insulating layer 133. In some embodiments, the first mold insulating layer 131 may include silicon oxide, and the second mold insulating layer 133 may include silicon nitride.

In some embodiments, a silane (SiH₄) gas and an ammonia (NH₃) gas may be used in a process of forming the mold layer 130. Accordingly, in the process of forming the mold layer 130, a significant amount of hydrogen (H₂), which is an unwanted by-product, may be collected inside the mold layer 130. Because H₂ may influence other elements in a subsequent process and degrade the performance of a semiconductor device, a process of removing H₂ may be performed.

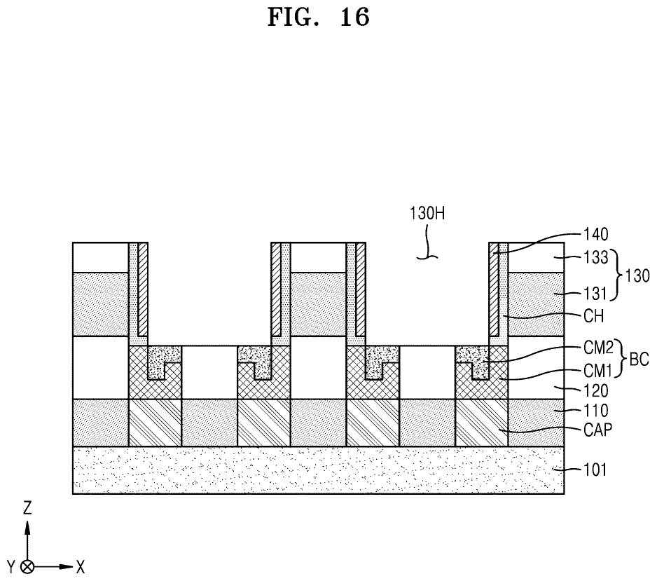

In the process of removing H₂, the exposed top surfaces of the contact sacrificial layers BCS may also be influenced. However, in a method of fabricating a semiconductor device, because a replacement process in which the contact sacrificial layers BCS are replaced with contact structures BC (see FIG. 16) is performed, the influence of H₂ in the final structure of the semiconductor device may be minimized.

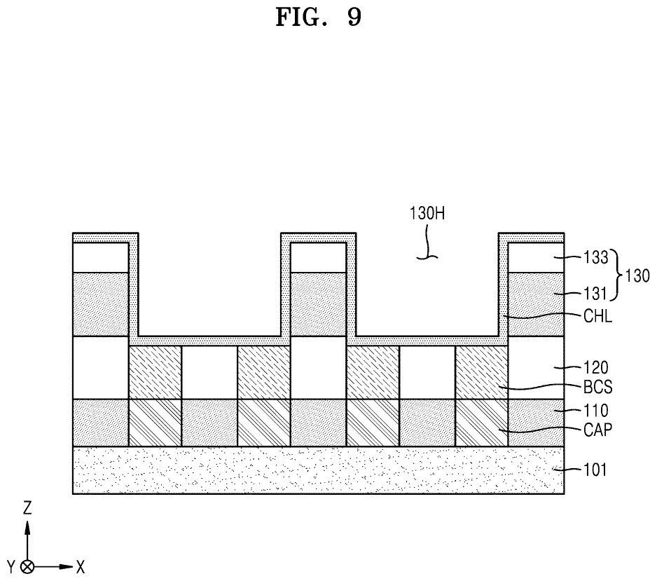

Referring to FIG. 9, an oxide semiconductor material layer CHL may be conformally formed on the inner walls of the mold openings 130H.

In some embodiments, the oxide semiconductor material layer CHL may include indium (In). For example, the oxide semiconductor material layer CHL may include at least one selected from the group consisting of IGZO, Sn-doped IGZO, W-doped IGZO, and IZO.

In some embodiments, the oxide semiconductor material layer CHL may be formed by using at least one selected from the group consisting of chemical vapor deposition (CVD), low-pressure CVD, plasma-enhanced CVD, metalorganic CVD (MOCVD), and atomic layer deposition.

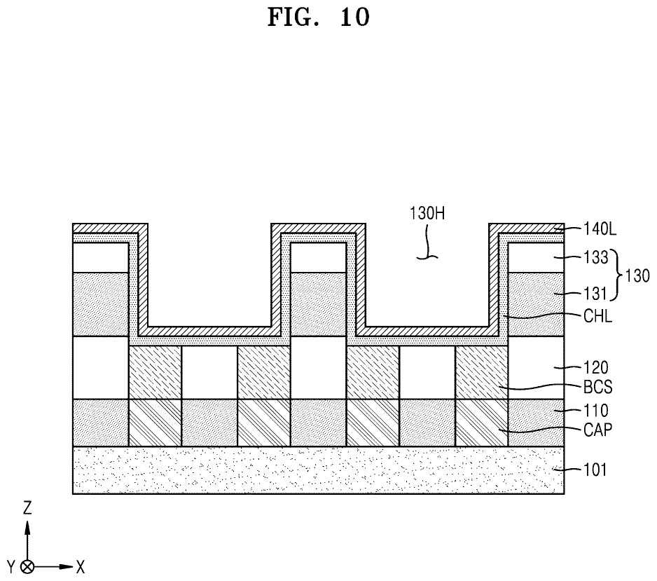

Referring to FIG. 10, a first gate dielectric material layer 140L may be conformally formed on the oxide semiconductor material layer CHL.

In some embodiments, the first gate dielectric material layer 140L may include a high-k dielectric material having a higher dielectric constant than silicon oxide.

In some embodiments, the first gate dielectric material layer 140L may be formed by using at least one selected from the group consisting of CVD, low-pressure CVD, plasma-enhanced CVD, MOCVD, and atomic layer deposition.

Referring to FIG. 11, a vertical channel layer CH and a first gate dielectric layer 140 may be formed on a sidewall of the mold layer by performing an etching process on the oxide semiconductor material layer CHL and the first gate dielectric material layer 140L.

The etching process may include an etch back process or a dry etching process. Accordingly, a plurality of vertical channel layers CH and a plurality of first gate dielectric layers 140 may be formed on sidewalls of the second insulating layers 120 and an upper wall of the capacitor CAP, forming the mold openings 130H. One vertical channel layer CH may have an L-shape (or a shape symmetrical with the L-shape).

When the vertical channel layer CH includes an oxide semiconductor material such as IGZO, a process of supplying oxygen (O₂) may increase the performance of the vertical channel layer CH. However, it is substantially impossible to supply O₂ to only the vertical channel layer CH, and thus, O₂ may influence other elements around the vertical channel layer CH.

As described above, in the process of supplying O₂, the exposed top surfaces of the contact sacrificial layers BCS may be oxidized. However, in a method of fabricating a semiconductor device, because a replacement process in which the contact sacrificial layers BCS are replaced with contact structures BC (see FIG. 16) is performed, the influence of oxidation on the final structure of the semiconductor device may be minimized.

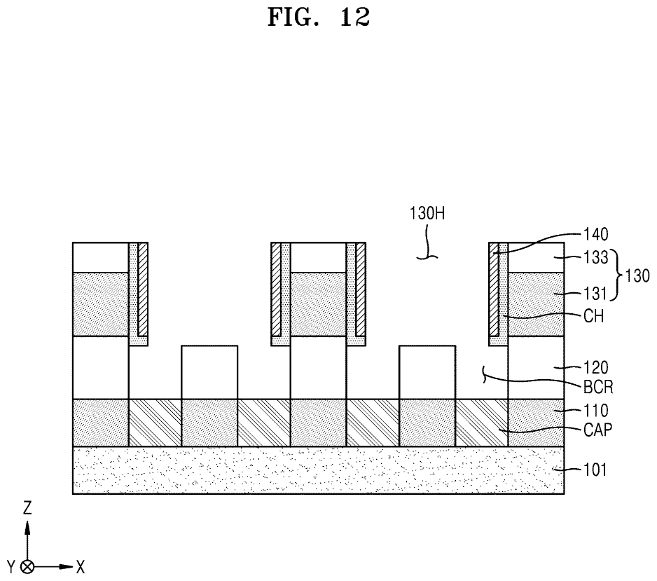

Referring to FIG. 12, the contact sacrificial layers BCS may be removed.

The top surfaces of the contact sacrificial layers BCS may include portions that have been influenced by H₂ and O₂ in the preceding processes. The contact sacrificial layers BCS including these portions may be completely removed by a wet etching process.

Accordingly, a plurality of empty spaces may be formed in places from which the contact sacrificial layers BCS have been removed. Because the contact structures BC (in FIG. 16) may be respectively formed in the empty spaces in a succeeding process, the empty spaces may be referred to as contact forming spaces BCR. The top surfaces of the capacitors CAP may be exposed by the contact forming spaces BCR.

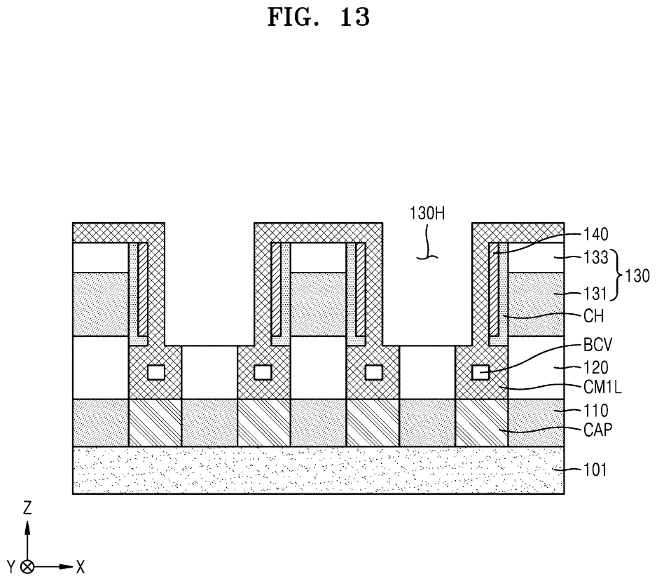

Referring to FIG. 13, a first contact metal layer CM1L may be conformally formed to cover the mold layer 130, the plurality of vertical channel layers CH, the first gate dielectric layers 140, and the contact forming spaces BCR.

In some embodiments, the first contact metal layer CM1L may include Mo, Ru, or TiN.

In some embodiments, the first contact metal layer CM1L may be formed by using at least one selected from the group consisting of CVD, low-pressure CVD, plasma-enhanced CVD, MOCVD, and atomic layer deposition.

In the process of forming the first contact metal layer CM1L, a void BCV may be formed in a central portion of each of the contact forming spaces BCR. The first contact metal layer CM1L may be conformally formed on the inner wall of each of the contact forming spaces BCR, inner walls of a contact forming space BCR may include for example, sidewalls of second insulating layers, and a top surface of a capacitor, and may thus not be formed in the central portion of each of the contact forming spaces BCR.

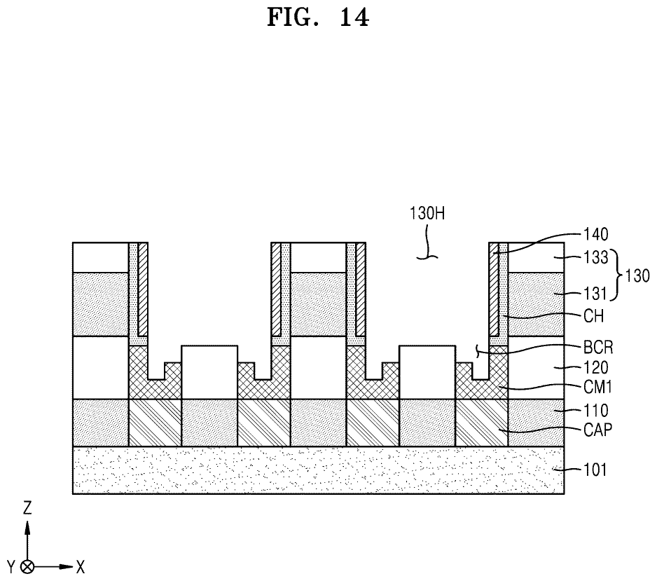

Referring to FIG. 14, the first contact metal CM1 having a stepped shape may be formed in each of the contact forming spaces BCR by performing an etching process on the first contact metal layer CM1L.

The etching process may include a wet etching process. Accordingly, because isotropic etching is performed on the first contact metal layer CM1L, the first contact metal CM1 may have a stepped shape influenced by the void BCV.

In this case, the topmost surface of the first contact metal CM1 may be in contact with the bottom surface of a vertical channel layer CH, and the bottom surface of the first contact metal CM1 may be in contact with the top surface of a capacitor CAP.

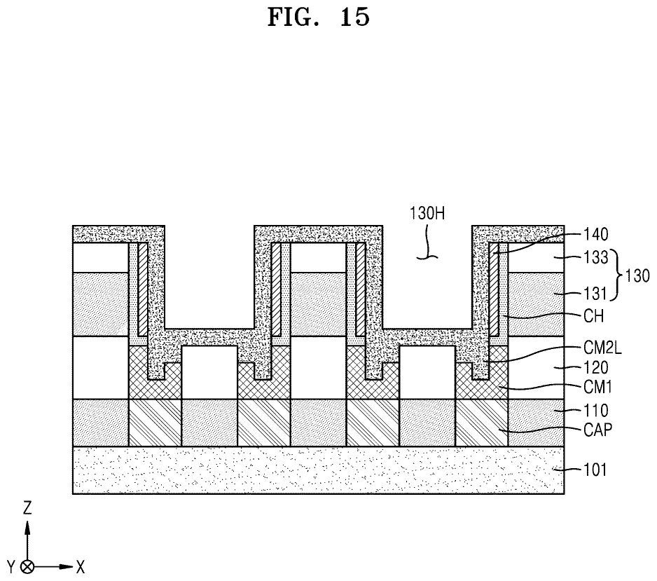

Referring to FIG. 15, a second contact metal layer CM2L may be conformally formed to cover the mold layer 130, the plurality of vertical channel layers CH, the first gate dielectric layers 140, and the plurality of first contact metals CM1. In embodiments, the second contact metal layer CM2L may fill the void BCV formed in a central portion of each of the contact forming spaces BCR.

The second contact metal layer CM2L may completely fill the stepped shapes of the first contact metals CM1, thereby making a top surface of the convex-concave portions flat. In some embodiments, the second contact metal layer CM2L may include Ti. When the second contact metal layer CM2L includes Ti having excellent H₂ capture effect, the second contact metal layer CM2L may prevent the diffusion of H₂ generated in a succeeding heat treatment process.

In some embodiments, the second contact metal layer CM2L may be formed by using at least one method selected from the group consisting of CVD, low-pressure CVD, plasma-enhanced CVD, MOCVD, and atomic layer deposition.

Referring to FIG. 16, an etching process may be performed on the second contact metal layer CM2L, so that the second contact metal CM2 having an inverted L-shape (or a shape symmetrical with the inverted L-shape) may be formed on each of the first contact metals CM1.

The etching process may include a wet etching process. Accordingly, because isotropic etching is performed on the second contact metal layer CM2L, the second contact metal CM2 may have a flat top surface.

In some embodiments, the second contact metal CM2 may be in contact with a first contact metal CM1 and may not be in contact with either the vertical channel layer CH or the capacitor CAP.

Through the processes described above, a contact structure BC including the first contact metal CM1 and the second contact metal CM2 may be formed.

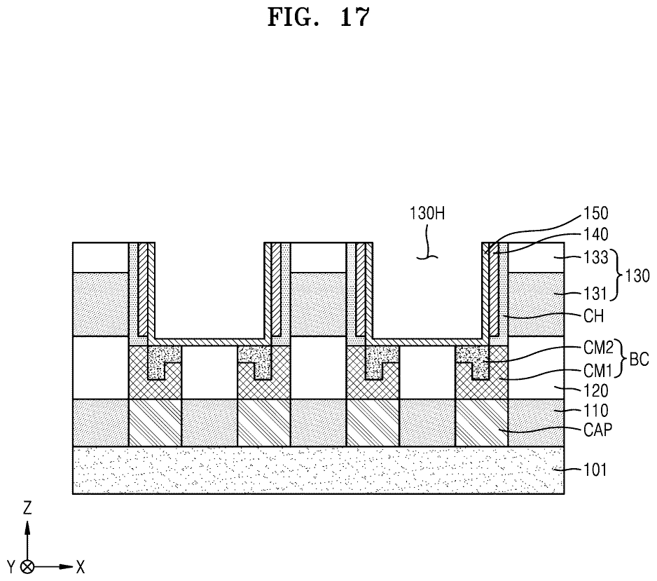

Referring to FIG. 17, a second gate dielectric layer 150 may be conformally formed on a plurality of first gate dielectric layers 140, a plurality of contact structures BC, and the second insulating layer 120.

In some embodiments, the second insulating layer 120 may include a high-k dielectric material having a higher dielectric constant than silicon oxide.

In some embodiments, the second gate dielectric layer 150 may be formed by using at least one selected from the group consisting of CVD, low-pressure CVD, plasma-enhanced CVD, MOCVD, and atomic layer deposition.

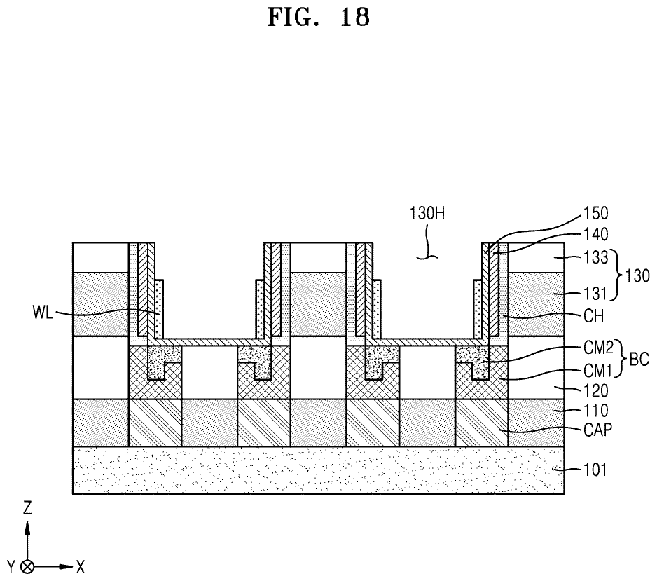

Referring to FIG. 18, word lines WL may be respectively formed on opposite inner sidewalls of the second gate dielectric layer 150.

The word lines WL may be formed by conformally forming a word line material layer on an inner wall of the second gate dielectric layer 150 and leaving a pair of word lines WL on opposite sidewalls of the second gate dielectric layer 150 by performing an anisotropic etching process or a recess process on the word line material layer.

In some embodiments, the word lines WL may include Ti, TiN, Ta, TaN, Mo, Ru, W, WN, TiSiN, WSiN, polysilicon, or a combination thereof.

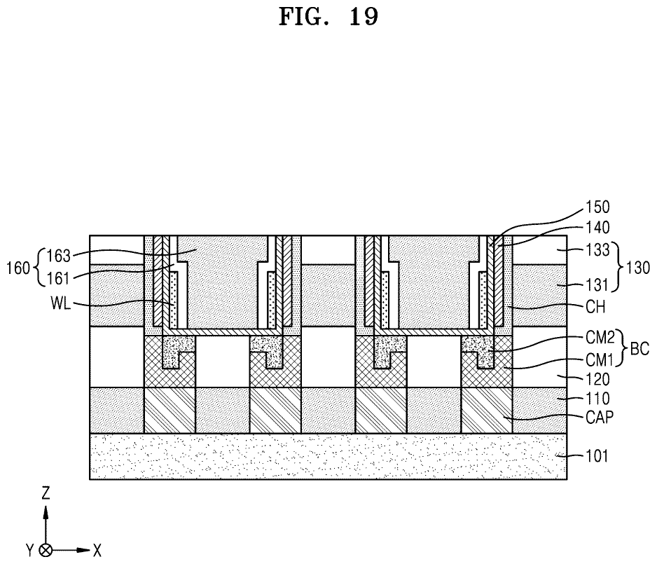

Referring to FIG. 19, an internal insulating layer 160 may be formed in each of the mold openings 130H.

In some embodiments, the internal insulating layer 160 may be formed in one mold opening 130H to cover the pair of word lines WL and the second gate dielectric layer 150. A first internal insulating layer 161 and a second internal insulating layer 163 may be included in the internal insulating layer 160.

In detail, a pair of first internal insulating layers 161 may be conformally formed to cover the pair of word lines WL, and the second internal insulating layer 163 may be formed between the first internal insulating layers 161 that face each other. In some embodiments, the first internal insulating layers 161 may include silicon nitride, and the second internal insulating layer 163 may include silicon oxide.

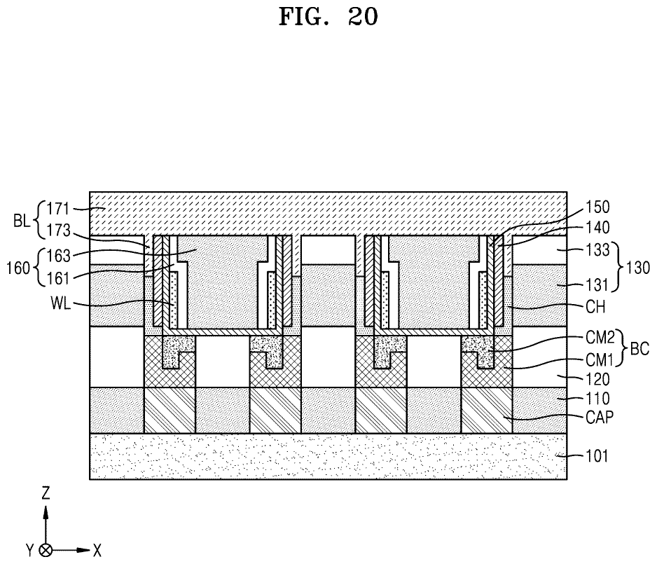

Referring to FIG. 20, a recess may be formed by etching an upper portion of each of the plurality of vertical channel layers CH.

The recess may be formed to expose a portion of a sidewall of one mold layer 130 and a portion of a sidewall of one first gate dielectric layer 140 by selectively etching each of the vertical channel layers CH.

A bit line BL may be formed to fill the recess and extend in the first horizontal direction (the X direction). The bit line BL may include a horizontal extension 171 and a plurality of vertical protrusions 173 protruding downward from the horizontal extension 171. The vertical protrusions 173 may be respectively in contact with the plurality of vertical channel layers CH.

Referring back to FIG. 2, the carrier substrate 101 may be removed from the structure described above. The semiconductor device 10 may be fabricated by using the method described above.

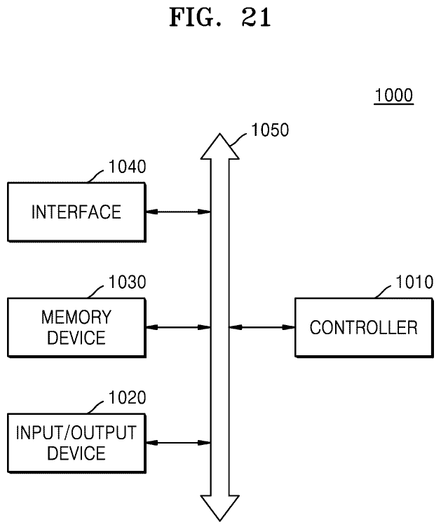

FIG. 21 is a block diagram of a system 1000 including a semiconductor device, according to an embodiment.

Referring to FIG. 21, the system 1000 may include a controller 1010, an input/output device 1020, a memory device 1030, an interface 1040, and a bus 1050.

The system 1000 may include a mobile system or a system that transmits or receives information. In some embodiments, the mobile system may include a portable computer, a web tablet, a mobile phone, a digital music player, or a memory card.

The controller 1010 may control an execution program in the system 1000 and may include a microprocessor, a digital signal processor, a microcontroller, or the like.

The input/output device 1020 may be used to input data to or output data from the system 1000. The system 1000 may be connected to and may exchange data with an external device, e.g., a personal computer (PC) or a network, through the input/output device 1020. For example, the input/output device 1020 may include a touch screen, a touchpad, a keyboard, or a display.

The memory device 1030 may store data for the operation of the controller 1010 or data processed by the controller 1010. The memory device 1030 may include the semiconductor device 10 or 20 described above.

The interface 1040 may correspond to a data transmission passage between the system 1000 and an external device. The controller 1010, the input/output device 1020, the memory device 1030, and the interface 1040 may communicate with one another through the bus 1050.

While the inventive concept has been particularly shown and described with reference to embodiments thereof, it will be understood that various changes in form and details may be made therein without departing from the spirit and scope of the following claims.

What is claimed is:

1. A semiconductor device comprising:
a capacitor;
a contact structure arranged on the capacitor and including a first contact metal and a second contact metal, the first contact metal being in contact with the capacitor, and the second contact metal not being in contact with the capacitor and being in contact with the first contact metal;
a vertical channel layer extending on the first contact metal in a vertical direction and including an oxide semiconductor material including indium;
a first gate dielectric layer in contact with a sidewall of the vertical channel layer;
a second gate dielectric layer in contact with a top surface of the second contact metal and a sidewall of the first gate dielectric layer;
a word line on an inner wall of the second gate dielectric layer; and
a bit line in contact with a top surface of the vertical channel layer and extending in a horizontal direction.

2. The semiconductor device of claim 1, wherein
the first contact metal includes one of molybdenum, ruthenium, or titanium nitride, and
the second contact metal includes titanium.

3. The semiconductor device of claim 1, wherein the vertical channel layer is arranged on a top surface of the first contact metal and is not arranged on the top surface of the second contact metal.

4. The semiconductor device of claim 3, wherein the second gate dielectric layer is arranged on the top surface of the second contact metal and is not arranged on the top surface of the first contact metal.

5. The semiconductor device of claim 4, wherein
the second contact metal has an inverted L-shape, and
a level of the top surface of the first contact metal is substantially equal to a level of the top surface of the second contact metal in the vertical direction.

6. The semiconductor device of claim 1, wherein a first length of the first gate dielectric layer in the vertical direction is less than a second length of the second gate dielectric layer in the vertical direction.

7. The semiconductor device of claim 1, wherein, in the vertical direction, the second gate dielectric layer is between the second contact metal and the word line.

8. The semiconductor device of claim 1, wherein
the bit line includes a horizontal extension and a vertical protrusion protruding from the horizontal extension, and
a bottom surface of the vertical protrusion of the bit line is in contact with the top surface of the vertical channel layer.

9. The semiconductor device of claim 8, wherein a sidewall of the vertical protrusion of the bit line is in contact with the first gate dielectric layer and not in contact with the second gate dielectric layer.

10. A semiconductor device comprising:
a peripheral circuit region including a peripheral circuit transistor; and
a cell array region on the peripheral circuit region,
wherein the cell array region includes:
a cell wiring structure;
a bit line extending in a horizontal direction on the cell wiring structure;
a vertical channel layer extending on the bit line in a vertical direction and including an oxide semiconductor material including indium;
a first gate dielectric layer in contact with a sidewall of the vertical channel layer;
a second gate dielectric layer in contact with a sidewall of the first gate dielectric layer;
a word line on an inner wall of the second gate dielectric layer;
a contact structure arranged on the vertical channel layer and the second gate dielectric layer and including a first contact metal and a second contact metal, the first contact metal being in contact with the vertical channel layer, and the second contact metal being in contact with the second gate dielectric layer and the first contact metal; and
a capacitor on the contact structure.

11. The semiconductor device of claim 10, wherein
the first contact metal includes one of molybdenum, ruthenium, or titanium nitride, and
the second contact metal includes titanium.

12. The semiconductor device of claim 10, wherein
the first contact metal is in contact with the capacitor, and
the second contact metal is not in contact with the capacitor.

13. The semiconductor device of claim 12, wherein
the second contact metal has an L-shape, and
a level of a bottom surface of the first contact metal is substantially equal to a level of a bottom surface of the second contact metal in the vertical direction.

14. The semiconductor device of claim 10, wherein
the peripheral circuit region includes a peripheral circuit wiring structure,
a first bonding pad is arranged in the cell wiring structure,
a second bonding pad is arranged in the peripheral circuit wiring structure, and
a bottom surface of the first bonding pad is in contact with a top surface of the second bonding pad.

15. A method of fabricating a semiconductor device, the method comprising:
forming a capacitor on a substrate;
forming a contact sacrificial layer on the capacitor;
forming a mold layer vertically above the contact sacrificial layer, the mold layer protruding in a vertical direction;
forming an oxide semiconductor material layer conformally covering the contact sacrificial layer and the mold layer;
forming a gate dielectric material layer covering the oxide semiconductor material layer;
forming a vertical channel layer and a first gate dielectric layer on a sidewall of the mold layer by etching the oxide semiconductor material layer and the gate dielectric material layer;
forming a contact forming space on the capacitor by removing the contact sacrificial layer, the contact forming space being defined by a first sidewall of an insulating layer, a second sidewall of the insulating layer and a top surface of the capacitor;
forming a first contact metal layer conformally covering the first gate dielectric layer and the first sidewall of the insulating layer, the second sidewall of the insulating layer, and the top surface of the capacitor defining the contact forming space;
forming a first contact metal by etching the first contact metal layer;
forming a second contact metal on the first contact metal;
forming a second gate dielectric layer conformally covering the first gate dielectric layer and the second contact metal;
forming a word line on an inner wall of the second gate dielectric layer; and
forming a bit line contacting the vertical channel layer and extending in a horizontal direction.

16. The method of claim 15, further comprising:
removing hydrogen from the mold layer after the forming of the mold layer; and
supplying oxygen to the vertical channel layer after the forming of the vertical channel layer and the first gate dielectric layer.

17. The method of claim 15, wherein, in the forming of the contact forming space, the top surface of the capacitor is exposed.

18. The method of claim 15, wherein
in the forming of the first contact metal layer,
the first contact metal layer is conformally formed on an inner wall of the contact forming space comprising the first sidewall of the insulating layer, the second sidewall of the insulating layer and the top surface of the capacitor, and
a void is formed in a central portion of the first contact metal layer in the contact forming space.

19. The method of claim 18, wherein, in the forming of the second contact metal, the second contact metal fills the void.

20. A semiconductor device fabricated by the method of claim 15.
